(19) United States
(12) Patent Application Publication
(10) Pub. No.: US 2023/0323558 A1
(43) Pub. Date: Oct. 12, 2023

(54) SUBSTRATE PROCESSING APPARATUS AND METHOD OF FABRICATING THE SAME

(71) Applicant: ASM IP Holding B.V., Ahmere (NL)

(72) Inventors: SungHoon Jun, Gyeonggi-do (KR); ByeongPil Park, Gyeonggi-do (KR); Shinya Ueda, Kai-shi (JP)

(21) Appl. No.: 18/123,508

(22) Filed: Mar. 20, 2023

Related U.S. Application Data
(60) Provisional application No. 63/322,857, filed on Mar. 23, 2022.

(51) Int. Cl. C25D 11/18; C23C 16/46; H01J 37/32

(52) U.S. Cl. CPC C25D 11/18; C23C 16/463; H01J 37/32724

(57) ABSTRACT

A method of manufacturing a cooling device of a substrate processing apparatus includes: providing an aluminum plate having a through hole; forming a temperature control portion by anodizing the aluminum plate; and arranging the temperature control portion below a substrate support portion, wherein the temperature control portion is arranged so that a support rod of the substrate support portion passes through the through hole.

### CROSS-REFERENCE TO RELATED APPLICATIONS

This application claims priority to U.S. Provisional Patent Application Serial No. 63/322,857 filed Mar. 23, 2022 titled SUBSTRATE PROCESSING APPARTAUS AND METHOD OF FABRICATING THE SAME, the disclosure of which is hereby incorporated by reference in its entirety.

### BACKGROUND

### 1. Field

One or more embodiments relate to a substrate processing apparatus and a method of fabricating the same, and more particularly, to an apparatus for maintaining a constant temperature in a reactor during a plasma process and a method of manufacturing the apparatus.

### 2. Description of the Related Art

In an in-situ plasma process for a substrate located in a reactor, the substrate is mounted on a susceptor installed on a heating block and gas is supplied to the substrate through a gas supply device, such as a showerhead, disposed opposite to the substrate. In the in-situ plasma process, high-frequency power is supplied to the gas supply device, and the gas is dissociated in a reaction space between the substrate and the gas supply device and adsorbed on the substrate to form a thin film on the substrate. At this time, the gas supply device functions as an upper electrode, and the heating block on which the substrate is mounted functions as a lower electrode. The heating block, the gas supply device, and the reactor supporting the heating block and the gas supply device are generally heated to a constant temperature to facilitate a process. For example, in order to induce a chemical reaction between the gas and the substrate, the substrate is heated through the heating block in addition to a plasma, thermal energy is supplied to the substrate, and thus, the gas supply device and the reactor are correspondingly heated to a certain temperature. In order to prevent overheating due to high temperature, the reactor is additionally provided with a cooling device. For example, an air cooling system for supplying external air or a liquid cooling system for supplying a liquid is additionally installed in the gas supply device or the reactor to maintain the gas supply device and the reactor at a constant temperature.

However, during the in-situ plasma process, the temperatures of the reaction space and the reactor rise due to plasma active species and ions. When the temperature is not controlled, the substrate processing is not smooth, and device quality may be low. In general, a fluctuation range of the reactor temperature needs to be controlled within a range of ±1 %, but when the reactor temperature rises due to plasma, a conventional air cooling method has a problem in that it is difficult to control the reactor temperature within the temperature fluctuation range, and a liquid cooling method has a problem in that the apparatus becomes complicated. For example, Korea Patent Publication No. 10-0331023 discloses a heater assembly having a cooling device, and in more detail, discloses a technical idea to uniformly control the temperature distribution of a susceptor by continuously circulating a coolant through a coolant inlet pipe and a coolant outlet pipe. However, this cooling method requires the additional installation of a coolant supply device and causes an increase in the maintenance cost.

The existing air cooling method or liquid cooling method apply to a system in which a cooling device, such as a fan or a liquid cooling path, is mainly installed on the outer surface of a reactor or a gas supply device to cool the outer wall of the reactor, and thus, the system has very low efficiency because it takes a long time for heat conduction. Therefore, it takes a considerable amount of time to respond to a temperature change inside the reactor, and there is a limit to temperature control. In addition, as the reactor and the gas supply device are also heated to a high temperature, it is not easy to suppress a temperature rise of the reactor due to plasma.

### SUMMARY

One or more embodiments include an apparatus for controlling the temperature of a reactor in a plasma process via a method different from the conventional air cooling method or liquid cooling method.

Additional aspects will be set forth in part in the description which follows and, in part, will be apparent from the description, or may be learned by practice of the presented embodiments of the disclosure.

According to one or more embodiments, a method of manufacturing a substrate processing apparatus includes: providing an aluminum plate having a through hole; forming a temperature control portion by anodizing the aluminum plate; and arranging the temperature control portion below a substrate support portion, wherein the temperature control portion is arranged so that a support rod of the substrate support portion passes through the through hole.

According to an example of the method of manufacturing a substrate processing apparatus, during the forming of the temperature control portion, the aluminum plate may be black anodized.

According to another example of the method of manufacturing a substrate processing apparatus, during the arranging of the temperature control portion, the aluminum plate may be fixed by at least one component of the substrate processing apparatus.

According to another example of the method of manufacturing a substrate processing apparatus, the aluminum plate may be fixed to the support rod.

According to another example of the method of manufacturing a substrate processing apparatus, the method may further include providing a connecting member on a lower surface of the substrate support portion, wherein the aluminum plate may be fixed to the substrate support portion through the connecting member.

According to another example of the method of manufacturing a substrate processing apparatus, the substrate support portion is configured to move up and down at least by a moving unit and the aluminum plate may be fixed to the moving unit.

According to another example of the method of manufacturing a substrate processing apparatus, during the arranging of the temperature control portion, the aluminum plate may be detachably seated on a chamber.

According to another example of the method of manufacturing a substrate processing apparatus, a lower surface of the aluminum plate may be in contact with an upper surface of the chamber, and radiant heat of a reaction space absorbed by the aluminum plate may be radiated to the outside through the chamber.

According to another example of the method of manufacturing a substrate processing apparatus, the method may further include post-treatment of the aluminum plate is performed during the forming of the temperature control portion, wherein, during the post-treatment, a roughness of the lower surface of the aluminum plate may be reduced.

According to another example of the method of manufacturing a substrate processing apparatus, the post-treatment may include grinding the lower surface of the aluminum plate.

According to another example of the method of manufacturing a substrate processing apparatus, the substrate processing apparatus may further include a heat transfer member disposed between the lower surface of the aluminum plate and the upper surface of the chamber, and radiant heat of a reaction space absorbed by the aluminum plate may be radiated to the outside through the heat transfer member and the chamber.

According to another example of the method of manufacturing a substrate processing apparatus, an inner peripheral surface of the aluminum plate in which the through hole of the aluminum plate is formed may include a first slope.

According to another example of the method of manufacturing a substrate processing apparatus, at least a portion of the support rod of the substrate support portion may include a second slope corresponding to the first slope.

According to another example of the method of manufacturing a substrate processing apparatus, the method may further include: performing an alignment operation of the temperature control portion while the support rod is raised so that the second slope may meet the first slope of the through hole of the aluminum plate.

According to another example of the method of manufacturing a substrate processing apparatus, the method may further include: aligning the temperature control portion to be coaxial with the support rod during the alignment operation.

According to another example of the method of manufacturing a substrate processing apparatus, the alignment operation may include: raising the support rod to separate the lower surface of the aluminum plate from the upper surface of the chamber; and lowering the support rod to bring the lower surface of the aluminum plate into contact with the upper surface of the chamber.

According to another example of the method of manufacturing a substrate processing apparatus, the aluminum plate may include: an upper plate extending in a first direction to provide the through hole; a lower plate extending in the first direction below the upper plate; and an extension portion extending in a second direction different from the first direction to connect the upper plate to the lower plate.

According to one or more embodiments, a substrate processing apparatus for performing a plasma process includes: a substrate support portion configured to support a substrate; a chamber configured to house the substrate support portion; and a temperature control portion arranged below the substrate support portion and configured to absorb radiant heat of a reaction space in the chamber generated during the plasma process.

According to an example of the substrate processing apparatus, the temperature control portion may include a black anodized aluminum plate.

According to one or more embodiments, a substrate processing method includes: loading a substrate onto a substrate support portion by locating a support rod at a first height; performing a process on the substrate by locating the support rod at a second height; and aligning the support rod with a temperature control portion arranged below the substrate support portion by locating the support rod at a third height.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic view of a substrate processing apparatus according to embodiments;

FIG. 2 is a view of an embodiment illustrating an arrangement position of a black wall plate mounted on a reactor;

FIG. 3 is a view of another embodiment illustrating an arrangement position of a black wall plate in a reactor;

FIG. 4 is a view of another embodiment illustrating an arrangement position of a black wall plate in a reactor;

FIG. 5 is a view of another embodiment illustrating an arrangement position of a black wall plate in a reactor;

FIG. 6 is a view illustrating that radiant heat of a heating block is absorbed by a black wall plate;

FIGS. 7 and 8 are views each illustrating the shape of a black wall plate and the arrangement of the black wall plate in a reactor;

FIG. 9 is a view illustrating a black wall plate disposed in a space below each heating block in a multi-reactor chamber in which a plurality of reactors is disposed;

FIG. 10 is a view illustrating a temperature change of a heating block before and after installing a black wall plate during a plasma process;

FIG. 11 is a schematic view of a substrate processing apparatus according to embodiments;

FIG. 12 is a view schematically illustrating a method of manufacturing a substrate processing apparatus according to embodiments;

FIG. 13 is a schematic view of a substrate processing apparatus according to embodiments;

FIGS. 14 to 16 are views schematically illustrating a substrate processing apparatus and a substrate processing method using the same, according to embodiments;

FIGS. 17 and 18 are views schematically illustrating a substrate processing method according to embodiments; and

FIGS. 19 to 21 are views illustrating an alignment operation of a temperature controller using the substrate processing apparatus according to embodiments

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

Hereinafter, embodiments of the disclosure will be described in detail with reference to the accompanying drawings.

In this regard, the embodiments may have different forms and should not be construed as being limited to the descriptions set forth herein. Rather, these embodiments are provided so that the disclosure will be thorough and complete, and will fully convey the scope of the disclosure to one of ordinary skill in the art.

The terminology used herein is for describing particular embodiments and is not intended to limit the disclosure. As used herein, the singular forms “a”, “an”, and “the” are intended to include the plural forms as well, unless the context clearly indicates otherwise. It will be further understood that the terms “includes”, “comprises” and/or “including”, “comprising” used herein specify the presence of stated features, integers, steps, processes, members, components, and/or groups thereof, but do not preclude the presence or addition of one or more other features, integers, steps, processes, members, components, and/or groups thereof. As used herein, the term “and/or” includes any and all combinations of one or more of the associated listed items.

It will be understood that, although the terms first, second, etc. may be used herein to describe various members, components, regions, layers, and/or sections, these members, components, regions, layers, and/or sections should not be limited by these terms. These terms do not denote any order, quantity, or importance, but rather are only used to distinguish one component, region, layer, and/or section from another component, region, layer, and/or section. Thus, a first member, component, region, layer, or section discussed below could be termed a second member, component, region, layer, or section without departing from the teachings of embodiments.

Embodiments of the disclosure will be described hereinafter with reference to the drawings in which embodiments of the disclosure are schematically illustrated. In the drawings, variations from the illustrated shapes may be expected because of, for example, manufacturing techniques and/or tolerances. Thus, the embodiments of the disclosure should not be construed as being limited to the particular shapes of regions illustrated herein but may include deviations in shapes that result, for example, from manufacturing processes.

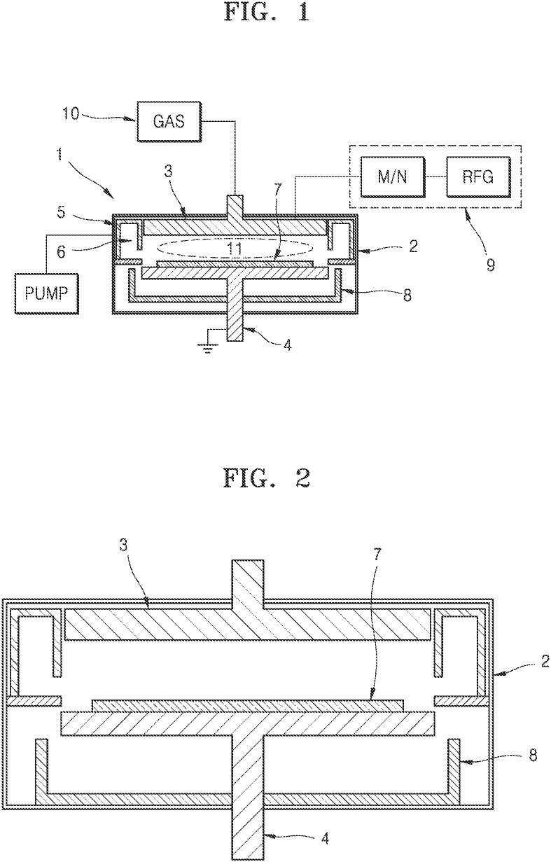

FIG. 1 is a schematic view of a substrate processing apparatus according to embodiments.

Referring to FIG. 1, in a reactor 1 of the substrate processing apparatus, a gas supply portion 3 and a substrate support portion 4 are disposed to face each other and apart from each other by a certain distance to form a reaction space 11. The gas supply unit 3 supplies a gas supplied through a gas supply line 10 to a substrate 7 through the reaction space 11. The gas supply unit 3 may be, for example, a showerhead. The substrate 7 is mounted on the substrate support portion 4, and the substrate support portion 4 may be moved up and down by a lifting device (not shown) for mounting, processing, and detachment of the substrate 7. The substrate support portion 4 may be a heating block and may supply thermal energy to the substrate 7. In an alternative embodiment, a susceptor (not shown) may be between the substrate 7 and the substrate support portion 4.

A gas remaining in the reaction space 11 after a chemical reaction on the substrate of FIG. 1 is exhausted to an exhaust pump through an exhaust path 6 of an exhaust portion 5. A high-frequency power supply unit 9 is connected to the reactor, so that the high-frequency power generated by the high-frequency power supply unit 9 is supplied to the reaction space and dissociates the gas in the reaction space 11 to generate plasma (a dashed line portion) As shown in the embodiment of FIG. 1, the gas supply unit 3 functions as an upper electrode, and the substrate support portion 4 disposed opposite thereto functions as a lower electrode. However, in an alternative embodiment, high-frequency power may be supplied to the reaction space through the substrate support portion 4. Dissociated gas ions and active species in the plasma react with the substrate and contribute to the formation of a thin film. In addition, the plasma process may contribute to the formation of a thin film on the substrate at a lower temperature. In FIG. 1, the high-frequency power supply unit 9 includes a high-frequency power generator (RF generator (RFG)) and a matching unit (matching network (M/N)).

The reactor 1 of FIG. 1 includes a temperature control portion 8. The temperature control portion 8 is in the form of a plate made of a metal material, anodized in black, and disposed to surround a lower portion of the heating block 4. The temperature control portion will be referred to as a black wall plate in this specification. The black wall plate 8 is obtained by black anodizing an Al plate, and has a technical effect of absorbing radiant heat from the heating block 4 and the plasma to control a temperature rise in the reactor. In addition, the black wall plate 8 is installed adjacent to the heating block 4 to increase the radiant heat absorption efficiency.

The black wall plate 8 is configured in a cylindrical shape to surround the heating block 4 and to receive the influence of plasma equally from all directions.

Radiant heat generated from the heating block 4 and plasma in the existing reactor is transferred to the gas supply portion 3 located above, but the gas supply part 3 is also heated to a high temperature, so that there is a problem in that a temperature rise of the reaction space due to radiant heat cannot be controlled. However, in the disclosure, by installing a black wall plate in a lower space of a reactor, in more detail, a space around a lower area of a heating block, there is a technical effect of absorbing radiant heat from the lower area of the heating block and directly controlling the temperature in a reaction space without separate cooling fluid supply.

In addition, there is a technical effect of discharging the radiant heat of the heating block, which could not be controlled in the past, to the outside of the reaction space through the black wall plate (e.g., a lower space of a chamber where substrate processing does not proceed, etc.).

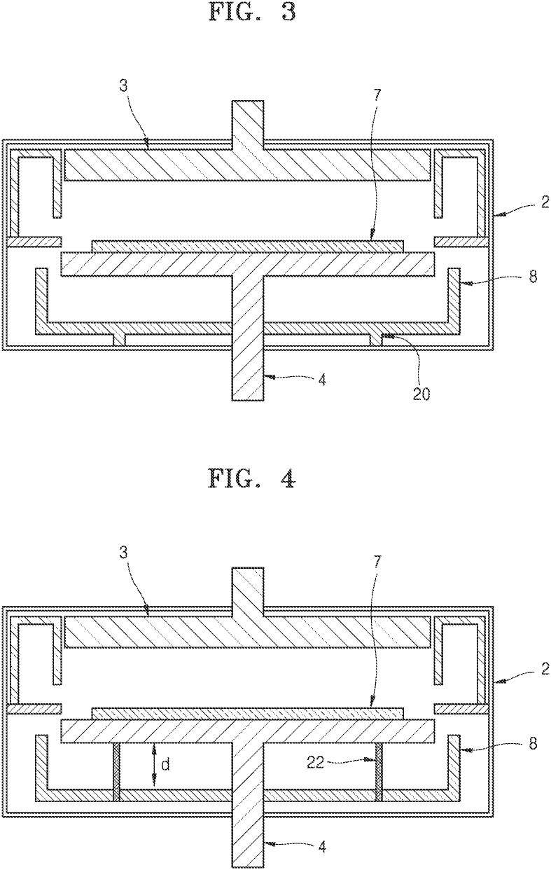

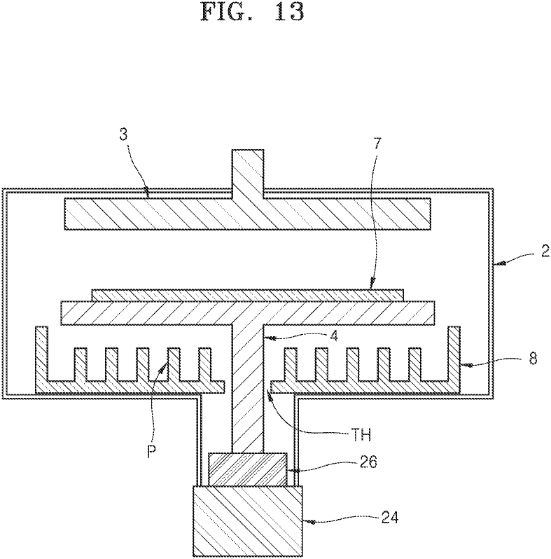

FIG. 2 is a view illustrating an arrangement position of the black wall plate 8 mounted on a reactor. In FIG. 2, the black wall plate 8 may be disposed on a bottom surface of a reactor wall 2. An embodiment in which the black wall plate 8 is disposed on the bottom surface of the reactor wall 2 will be described in more detail with reference to FIG. 10.

FIG. 3 is a view of another embodiment illustrating an arrangement position of the black wall plate 8 in a reactor. Referring to FIG. 3, the black wall plate 8 is supported by a support 20. A height of the support, when the heating block 4 is lowered for substrate loading/unloading, is configured such that a distance between a lower surface of the heating block 4 and a reactor bottom is greater than a distance between the bottom of the black wall plate 8 and the reactor bottom. Therefore, when the heating block 4 is lowered, the collision between the heating block 4 and the black wall plate 8 may be prevented.

FIG. 4 is a view of another embodiment illustrating an arrangement position of the black wall plate 8 in a reactor.

In FIG. 4, a black wall plate support unit 22 is provided on a lower surface of the heating block 4 and mechanically connects the heating block 4 and the black wall plate 8. Therefore, there is a technical effect that a distance d between the lower surface of the heating block 4 and a bottom surface of the black wall plate 8 may be kept constant. In an embodiment, the distance d may be 0. That is, the lower surface of the heating block 4 and the black wall plate 8 are in close contact with each other. Accordingly, radiant heat removal efficiency of the black wall plate 8 from the heating block and plasma may be further improved. In another embodiment, the distance d is configured to be less than a distance between the lower surface of the heating block 4 and a bottom surface of the reactor wall 2 when the heating block 4 is lowered for substrate loading/unloading. Accordingly, the collision between the heating block 4 and the black wall plate 8 may be prevented.

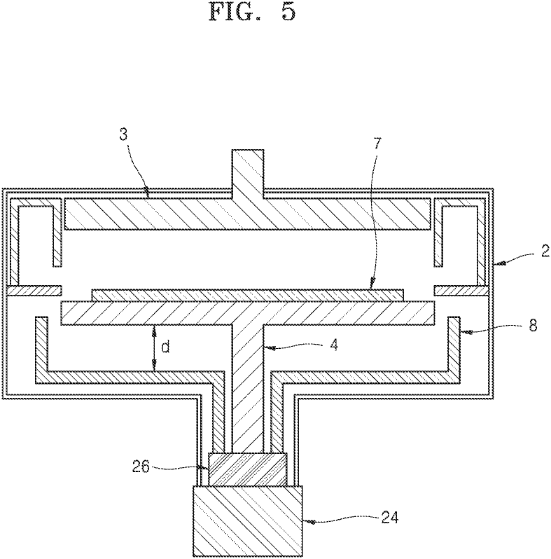

FIG. 5 is a view of another embodiment illustrating an arrangement position of the black wall plate 8 in a reactor.

In FIG. 5, the heating block 4 is supported by a driving unit (24 and 26). The driving unit includes a driving motor 24 and a contraction unit 26. The driving motor 24 transmits a driving force for moving the heating block 4 in a vertical direction to the contraction unit 26, and the contraction unit 26 facilitates vertical movement of the heating block 4 while contracting or relaxing in the vertical direction. In FIG. 5, the black wall plate 8 may be a part of the driving unit. In an embodiment, according to the contraction or relaxation of the contraction unit 26, the black wall plate 8 moves in the vertical direction together with the heating block 4. Therefore, there is a technical effect that the distance d between the heating block 4 and the black wall plate 8 may be kept constant.

In another embodiment, the driving motor 24 may be configured to move the heating block 4 in a horizontal direction, so that radiant heat may be uniformly removed in a reaction space.

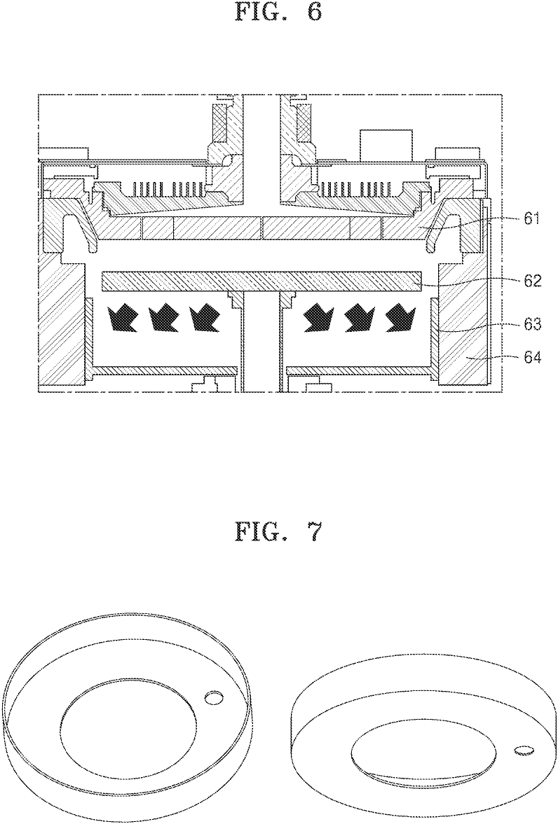

FIG. 6 is a view illustrating that radiant heat of a heating block is absorbed by a black wall plate. As shown in FIG. 6, as a plasma process proceeds in a reaction space between a shower head 61 and a heating block 62, the temperature of the reaction space may increase, and radiant heat generated due to this temperature increase may be accumulated in a vacuum chamber 64. A black wall plate 63 may absorb the radiant heat of this reaction space.

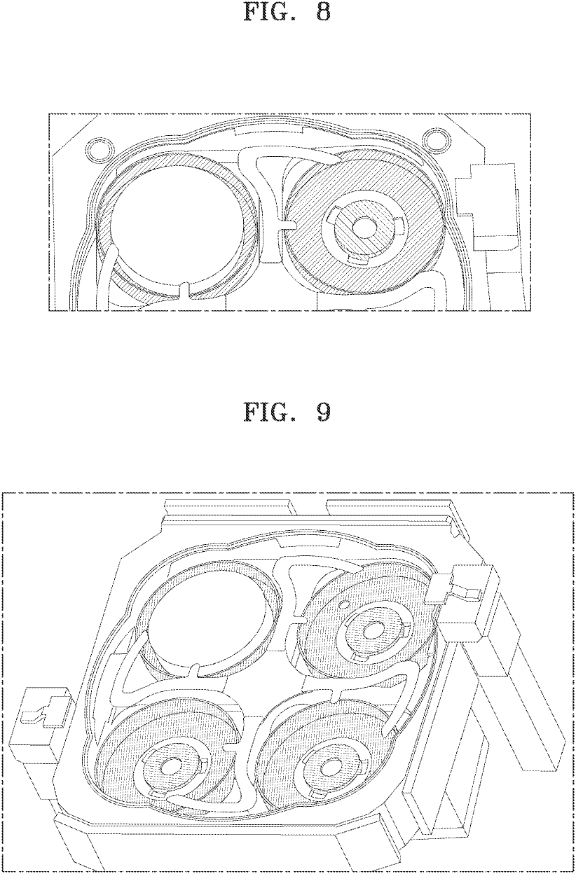

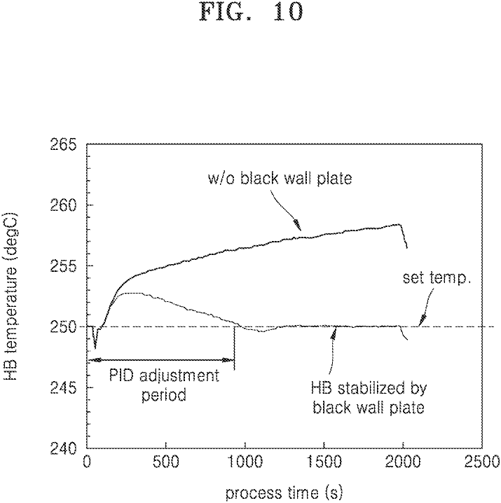

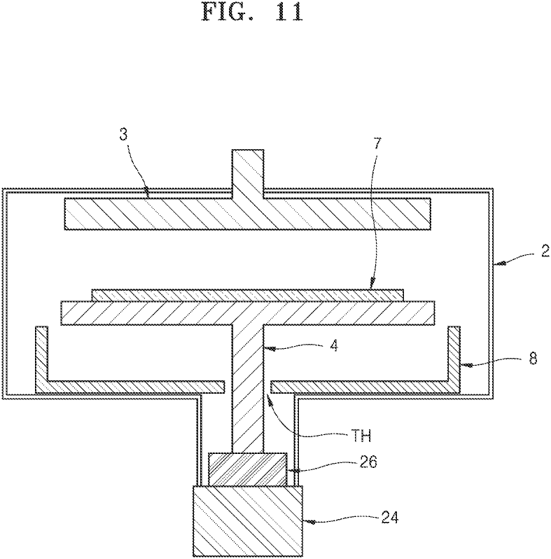

FIGS. 7 and 8 are views each illustrating the shape of a black wall plate and the arrangement of the black wall plate in a reactor.

Referring to FIG. 7, the black wall plate may have a shape corresponding to the shape of a substrate. For example, when the substrate is a semiconductor wafer and has a circular shape, the black wall plate may have a circular shape when viewed from above. In another example, when the substrate is a display substrate and has a rectangular shape, the black wall plate may have a rectangular shape when viewed from above.

Referring to FIG. 8, a state in which the black wall plate is disposed in a state in which a substrate support portion including a heating block is installed is shown on the left, and a state in which the black wall plate is disposed such that a support rod passes through a through hole of the black wall plate in a state in which a substrate support portion including a heating block is not installed is shown on the right.

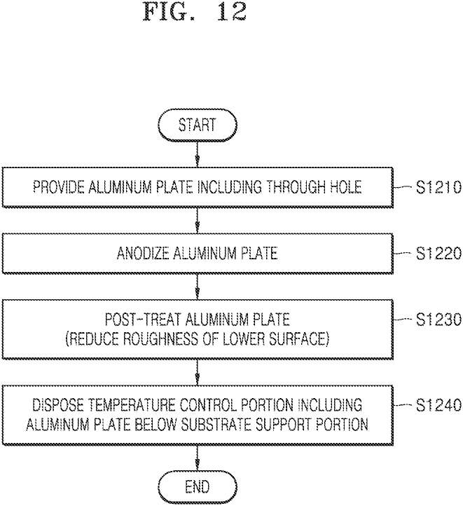

FIG. 9 is a view illustrating that a black wall plate is disposed in a space below each heating block in a multi-reactor chamber in which a plurality of reactors is disposed. As shown in FIG. 9, a substrate processing apparatus may be a multi-reactor chamber in which four reactors are disposed, and individual substrate support portion each including a heating block may form a reaction space together with a corresponding gas supply. These four reaction spaces may be formed in a single vacuum chamber. In other words, a plurality of gas supply portions, a plurality of substrate support portions, and a plurality of black wall plates may be disposed in a single vacuum chamber.

FIG. 10 is a view illustrating a temperature change of a heating block before and after installing a black wall plate during a plasma process.

In FIG. 10, when there is no black wall plate during the plasma process, the temperature of the heating block continues to rise compared to a set temperature (250° C.) by plasma radiant heat. However, when a black wall plate is used, the temperature is controlled through PID control (Proportional-Integral-Derivative control) via a temperature control device that supplies power to the heating block for about 1,000 seconds in the initial stage, and then the heating block temperature is stably controlled according to the set temperature (250° C.). Accordingly, the heating block temperature, which has not been normally controlled by plasma and thus rises in previous technologies, is stably controlled to a constant temperature.

As described above, according to embodiments of the inventive concept, by providing a black wall plate around a heating block, it is possible to prevent the temperature of the heating block from rising by plasma in a plasma process and to control the heating block temperature stably according to a set temperature. In particular, the black wall plate may absorb radiant heat and achieve a cooling effect by being black anodized. Accordingly, the black wall plate may stably control the temperature of the heating block without supplying a separate cooling fluid, and prevent the temperature increase of the heating block even during the plasma process.

FIG. 11 is a schematic view of a substrate processing apparatus according to embodiments. The substrate processing apparatus according to the embodiments may be a variation of the substrate processing apparatus according to the above-described embodiments. Hereinafter, repeated descriptions of the embodiments will not be given herein.

Referring to FIG. 11, the substrate processing apparatus may be configured to perform a plasma process. An example of the substrate processing apparatus may be a deposition apparatus or an etching apparatus for a semiconductor or display substrate, but the disclosure is not limited thereto. The substrate processing apparatus may be any device necessary for processing a substrate.

In some embodiments, the substrate processing apparatus may include a chamber, a substrate support portion 4, and a temperature control portion 8. The chamber may provide a reaction space for performing a process on the substrate 7 to be processed. For example, the chamber may include a reactor wall 2 defining a reaction space, and components for substrate processing such as the substrate support portion 4 and the temperature control portion 8 may be housed into the reactor wall 2.

In some further embodiments, the gas supply portion 3 may also be housed into the reactor wall 2. In an alternative embodiment, the gas supply portion 3 may be fixed to the reactor wall 2 of the chamber via a fixing member (not shown). In some examples, the gas supply portion 3 may be configured to supply a gas to the reaction space. In a further example, the gas supply portion 3 may be further configured to apply plasma power to the reaction space.

The substrate support portion 4 may be configured to support the substrate 7. The substrate 7 mounted on the substrate support portion 4 may be processed by at least one gas introduced into the reaction space in the chamber. For example, the gas supply portion 3 may be disposed to face the substrate support portion 4, so that the at least one gas may be introduced into the reaction space through the gas supply portion 3.

The substrate support portion 4 may include a support rod and a susceptor. The susceptor may extend in the same direction as an extension direction of a substrate (e.g., a horizontal direction), and the support rod may extend in a direction different from the extension direction of the substrate (e.g., a vertical direction). In a further embodiment, the substrate support portion 4 may further include a heating block configured to heat a substrate.

In some embodiments, the substrate support portion 4 may be moved by the driving unit 24. For example, the driving unit 24 may be configured to vertically move the moving unit 26 connected to the substrate support portion 4. A substrate may be loaded/unloaded on the substrate support portion 4 by the vertical movement of the moving unit 26 by the driving unit 24. In a further embodiment, the driving unit 24 may be configured to rotate the moving unit 26. In another embodiment, the driving unit 24 may be configured to tilt the moving unit 26. The substrate support portion 4 may be directly connected to the driving unit 24 without the moving unit 26.

The temperature control portion 8 may be below the substrate support portion 4. The temperature control portion 8 may be configured to absorb radiant heat of the reaction space in the chamber generated during the plasma process in the substrate processing apparatus. Radiant heat is heat generated due to radiant energy of electromagnetic waves, and may be generated by electromagnetic waves generated during the plasma process. The temperature control portion 8 may be configured to absorb the radiant heat instead of the substrate support portion 4.

In some embodiments, the temperature control portion 8 may include an aluminum plate, and in some embodiments, the aluminum plate may be anodized. In a further embodiment, the anodizing process may be implemented as a black anodizing process of black anodizing the aluminum plate. Because black absorbs radiant heat the best, the temperature control portion 8 implemented by black anodizing may achieve an optimal radiant heat absorption effect.

In some embodiments, as shown in FIG. 11, the temperature control portion 8 may have a through hole TH, and the support rod of the substrate support portion 4 may extend through the through hole TH. That is, the temperature control portion 8 may be arranged below the substrate support portion 4 so that the support rod of the substrate support portion 4 passes through the through hole TH of the temperature control portion 8.

The temperature control portion 8 may be in contact with the chamber. For example, a lower surface of the temperature control portion 8 and an upper surface of the chamber may be in contact with each other, and by the temperature control portion 8 absorbing electromagnetic waves or the like, radiant heat generated may be conducted from the temperature control portion 8 to the chamber by the contact. The adhesion between the temperature control portion 8 and the chamber may be increased by grinding so that heat conduction from the temperature control portion 8 to the chamber may be promoted. For example, the lower surface of the temperature control portion 8 may have a roughness of Ra 0.5 or less.

In an alternative embodiment, a heat transfer member with improved heat transfer efficiency may be disposed between the temperature control portion 8 and the chamber. For example, a heat transfer member may be disposed between a lower surface of the aluminum plate of the temperature control portion 8 and the upper surface of the chamber. The radiant heat of the reaction space absorbed by the aluminum plate may be radiated to the outside through the heat transfer member and the chamber.

In another embodiment, the temperature control portion 8 may be a portion of the chamber. For example, the temperature control portion 8 may be a part of a chamber wall facing a lower portion of the substrate support portion or may be embedded in the chamber wall.

In the conventional air cooling method or liquid cooling method, a cooling member is mainly installed on the outer surface of a reactor or a gas supply device. Accordingly, this method has disadvantages in that it takes a certain amount of time to respond to a temperature change inside the reactor and has a limitation in temperature control. However, in the disclosure, by disposing the temperature control portion 8 in the chamber of the substrate processing apparatus to absorb radiant heat generated in the chamber and transfer the radiant heat to the chamber so that the radiant heat is released from the chamber, it is possible to respond more quickly to the temperature change in the reactor and to achieve temperature control more easily.

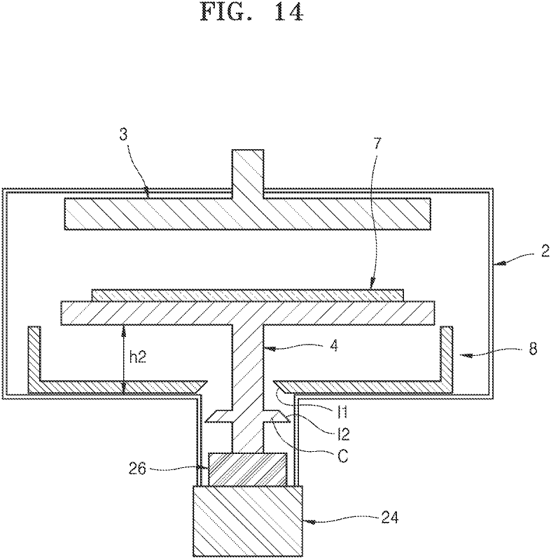

FIG. 12 is a view schematically illustrating a method of manufacturing a substrate processing apparatus according to embodiments. The method of manufacturing a substrate processing apparatus according to embodiments may be the method of manufacturing a substrate processing apparatus according to the above-described embodiments. Hereinafter, repeated descriptions of the embodiments will not be given herein.

Referring to FIG. 12, in operation S1210, an aluminum plate is first provided. For example, an aluminum plate may be processed to have a cylindrical shape, and an aluminum plate having a through hole may be provided by forming the through hole TH (of FIG. 11) in the center of the cylindrical aluminum plate. In some embodiments, the aluminum plate may be machined to further include an additional through hole (not shown) that provide a space for a lift pin to pass through.

Thereafter, in operation S1220, anodizing is performed on the aluminum plate. The anodized aluminum plate is chemically stabilized and has a high level of specific heat properties, so the aluminum plate may function as a temperature control portion that quickly absorbs heat. As a result, the temperature control portion may be formed by performing anodizing on the aluminum plate. In an alternative embodiment, as described above, the aluminum plate may be black anodized to promote absorption of radiant heat.

In an alternative embodiment, in operation S1230, the anodized aluminum plate may be post-treated to form the temperature control portion. As described above, when the temperature control portion is disposed to be in contact with a chamber, heat transfer efficiency may be increased by enhancing the adhesion between the temperature control portion and a bottom surface of the chamber. For this purpose, the post-treatment may be performed.

For example, a process for reducing the roughness of a lower surface of the aluminum plate may be performed during the post-treatment. For example, a lower surface of the anodized aluminum plate may be ground during the post-treatment. When the surface of an aluminum plate with reduced roughness is in contact with a chamber surface, the adhesion may increase, and as a result, the radiant heat that the aluminum plate has absorbed may be radiated to the outside through the chamber.

In operation S1240, after the temperature control portion is formed, the temperature control portion is disposed below a substrate support portion. In more detail, the temperature control portion may be arranged so that a support rod of the substrate support portion passes through the through hole of the aluminum plate. In some embodiments, as shown in FIG. 11, during the arranging of the temperature control portion, the aluminum plate may be detachably seated on the chamber. That is, the aluminum plate of the temperature control portion may be detachably seated without being fixed to a reactor wall of the chamber.

In another embodiment, during the arranging of the temperature control portion, the aluminum plate may be fixed by at least one component of the substrate processing apparatus. For example, the aluminum plate may be fixed to the support rod (see FIG. 1). As a specific example, the aluminum plate may be fixed to the support rod through a fixing member, and a fixing structure may be achieved through welding between the aluminum plate and the support rod.

In another example, the aluminum plate may be fixed to the substrate support portion (see FIG. 4). For example, the substrate support portion may be connected to the aluminum plate via a connecting member such as a black wall plate support unit (see 22 of FIG. 4), whereby the temperature control portion may be connected to the substrate support portion. In this case, the substrate processing apparatus may further include the connecting member (see 22 of FIG. 4) provided on a lower surface of the substrate support portion.

In some other examples, the aluminum plate may be fixed to the moving unit 26 (see FIG. 5). When the moving unit 26 moves up and down by the driving unit 24, because the substrate support portion and the aluminum plate are fixed to the moving unit 26, the substrate support portion and the aluminum plate may move up and down together with the movement of the moving unit 26.

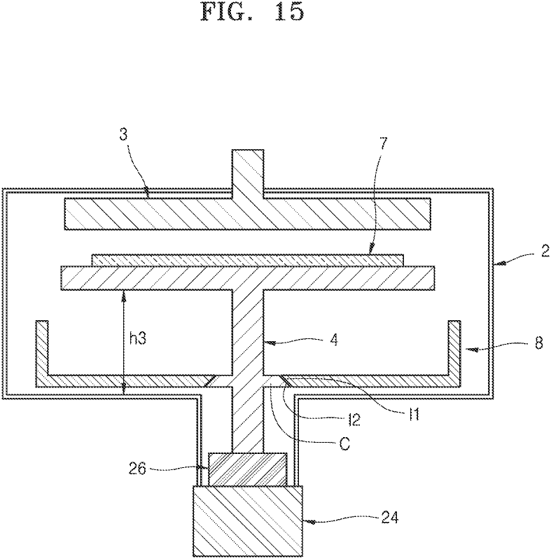

FIG. 13 is a schematic view of a substrate processing apparatus according to embodiments. The substrate processing apparatus according to the embodiments may be a variation of the substrate processing apparatus according to the above-described embodiments. Hereinafter, repeated descriptions of the embodiments will not be given herein.

Referring to FIG. 13, the temperature control portion 8 of the substrate processing apparatus may further include a plurality of protrusions P. The plurality of protrusions P are configured to increase a surface area of the temperature control portion 8, and may extend from an aluminum plate toward the substrate support portion 4.

For example, when the aluminum plate of the temperature control portion 8 has a cylindrical shape, the plurality of protrusions P may be formed in a concave space formed by the cylindrical shape. In an embodiment, each of the plurality of protrusions P may extend in a circle to surround a support rod when viewed in a plan view. Each of the plurality of protrusions P extending to surround all or part of the support rod may protrude from an upper surface of the aluminum plate. In some embodiments, the plurality of protrusions P may be formed of the same material as that of the aluminum plate. In a further alternative embodiment, the roughness of a surface of the plurality of protrusions P may be greater than that of a lower surface of the aluminum plate.

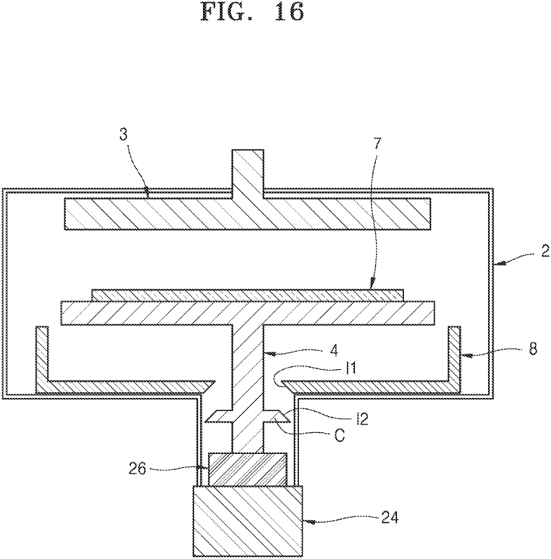

FIGS. 14 to 16 are views schematically illustrating a substrate processing apparatus and a substrate processing method using the same, according to embodiments. The substrate processing apparatus according to the embodiments may be a variation of the substrate processing apparatus according to the above-described embodiments. Hereinafter, repeated descriptions of the embodiments will not be given herein.

First, in order to describe a substrate processing apparatus according to embodiments, reference is made to FIG. 16 showing a substrate processing apparatus in an aligned state. As illustrated in FIG. 16, the substrate processing apparatus may include the temperature control portion 8 including an aluminum plate, and an inner peripheral surface of the aluminum plate may include a first slope I1. In more detail, the first slope I1 may be formed on the inner peripheral surface (of a portion in which a through hole is formed) of the aluminum plate.

At least a portion of a support rod of the substrate support portion 4 may include a second slope I2. For example, the support rod may include a main shaft extending from the driving unit 24 to a susceptor (and/or heating block) and an engaging portion C protruding from the main shaft, and an outer peripheral surface of the engaging portion C may include the second slope I2. In another example, the main shaft of the support rod may be formed to have the second slope I2.

The second slope I2 and the first slope I1 may correspond to each other. For example, the first slope I1 and the second slope I2 may have the same inclination. In an example, when the aluminum plate including the first slope I1 is lifted by the support rod including the second slope I2, the first slope I1 and the second slope I2 may contact each other to form a contact surface. In this case, the aluminum plate may move downward along the engaging portion (C) along the contact surface by the weight of the aluminum plate, and accordingly, the aluminum plate and the support rod may be aligned to be coaxial with each other.

FIGS. 14 to 16 show an alignment operation of the temperature control portion 8 using such a substrate processing apparatus. Referring to FIG. 14, the position of the temperature control portion 8 including the aluminum plate is moved due to gas flow, temperature change, pressure change, etc. in a chamber occurring during the process (e.g. deposition process) of the substrate processing apparatus, and the temperature control portion 8 may be disposed in a non-symmetrical state with respect to the center of the substrate support portion 4. That is, as the process progresses, a central axis of a black anodized aluminum plate of the temperature control portion 8 may not coincide with a central axis of the support rod of the substrate support portion 4.

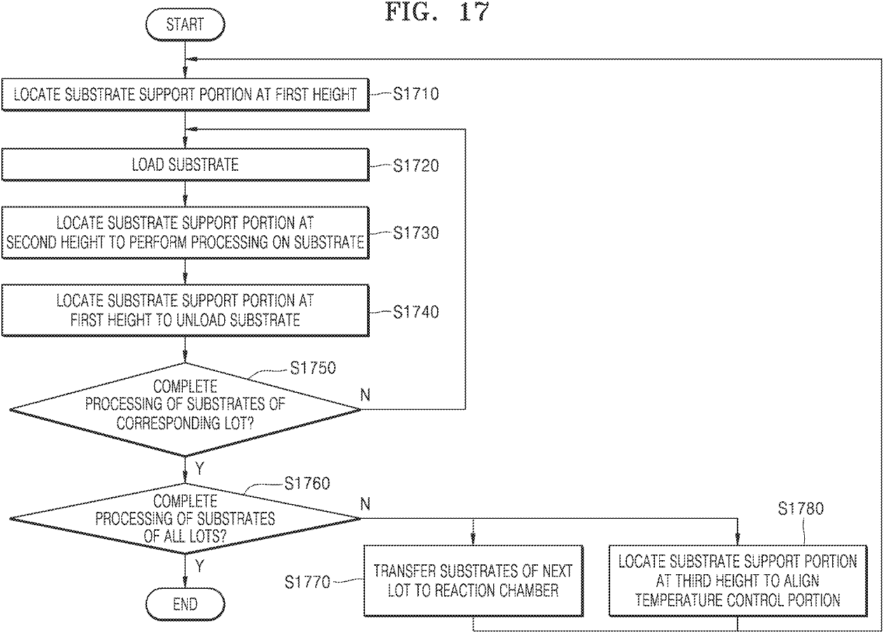

Referring to FIG. 15, in order to perform an alignment operation of the temperature control portion 8, a support rod may rise to a certain height. While the support rod is rising, the second slope I2 included in the support rod may contact the first slope I1 of a through hole of an aluminum plate. As the support rod continues to rise, the aluminum plate of the temperature control portion 8 may be lifted apart from a chamber wall while maintaining the contact with the temperature control portion 8. That is, a lower surface of the aluminum plate may be apart from an upper surface of the chamber.

In a state in which the aluminum plate and the chamber are separated from each other, the temperature control portion 8 may move under the influence of gravity. In more detail, the temperature control portion 8 may move along the inclination of a contact surface of the first slope I1 and the second slope I2.

The movement along the inclination may include a vertical component and a horizontal component. In this case, the temperature control portion 8 may move downward by the vertical component, and may move in a horizontal direction to be coaxial with a central axis of the support rod by the horizontal component. As a result, self-alignment between the aluminum plate and the support rod may be achieved.

Next, referring to FIG. 16, a support rod is lowered, and accordingly, an aluminum plate of the temperature control portion 8 is lowered, so that a lower surface of the temperature control portion 8 and an upper surface of a chamber meet each other. The support rod may continue to be lowered so that the second slope I2 included in the support rod may be separated from the first slope I1 of a through hole of the aluminum plate. Therefore, a black anodized aluminum plate may be seated on the chamber in a self-aligned state, and while a subsequent process is being performed, the temperature control portion 8 may perform a heat dissipation function while maintaining contact with the chamber and being co-axial with the substrate support portion 4.

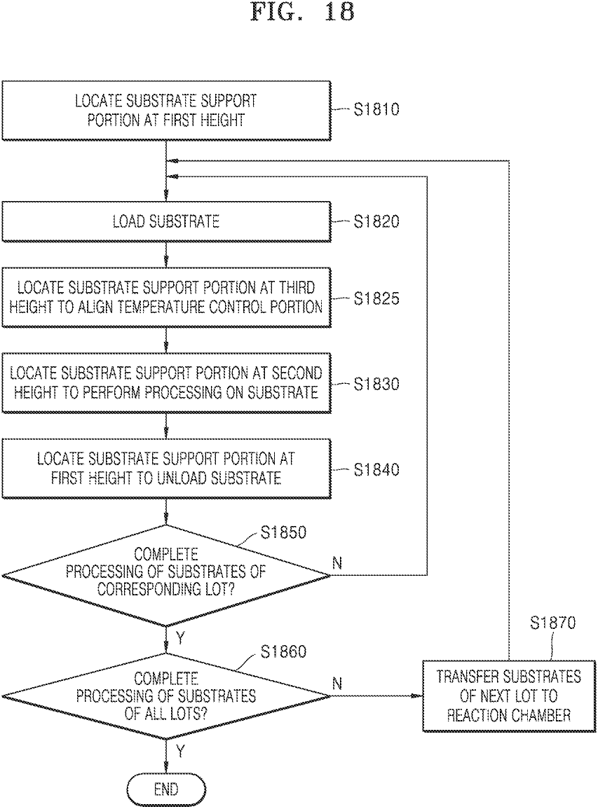

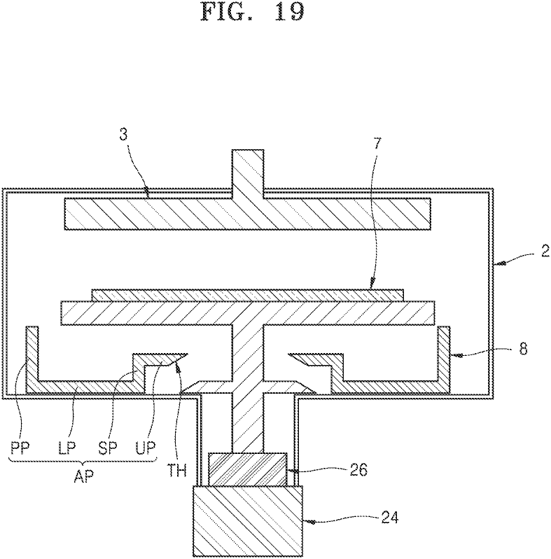

FIGS. 17 and 18 are views schematically illustrating a substrate processing method according to embodiments. The substrate processing method according to the embodiments may use the substrate processing apparatus according to the above-described embodiments. Hereinafter, repeated descriptions of the embodiments will not be given herein.

Referring to FIG. 17, first, in operation S1710, a substrate support portion is located at a first height, and in operation S1720, the substrate is loaded. For example, the substrate support portion may be lowered and located at a height corresponding to a substrate inlet, e.g. gate valve, of a lower space of the chamber, and a robot arm may transfer the substrate from the outside to a substrate support portion through the substrate inlet.

After the loading of the substrate, in operation S1730, the substrate support portion is located at a second height to perform processing on the substrate. For example, the substrate support portion receiving the substrate at the first height may be raised and located at a height to form a reaction space together with a gas supply unit, and the substrate may be processed by a gas supplied by the gas supply unit.

Thereafter, in operation S1740, the substrate support portion is located at the first height again to unload the substrate. As described above, the substrate support portion may be located at a height corresponding to the substrate inlet of the lower space of the chamber by being lowered from the second height, and the robot arm may lift the substrate on the substrate support portion and transfer the substrate to the outside through the substrate inlet.

The substrate loading, process performing, and substrate unloading operations may be repeated as one cycle until all substrates of a corresponding lot are processed. After the cycle, in operation S1750, it is determined whether all the substrates of the corresponding lot have been processed, and in operation S1750, when the processing of the substrates of the corresponding lot is completed, processing of substrates of the next lot is performed. To this end, in operation S1760, it is determined whether substrates of all lots have been processed, and when the substrates of all lots are not processed, operation S1770 of transferring substrates of the next lot to a reaction chamber may be performed.

Because the reaction space is idle during the transfer operation, in some embodiments, operation S1780 of locating the substrate support portion at a third height to align a temperature control portion may be performed. In other words, as described above in FIG. 15, by lifting the substrate support portion 4 (of FIG. 15) to the third height, self-alignment with respect to the temperature control portion 8 (of FIG. 15) may be performed. Thereafter, in operation S1710, the substrate support portion may be located at the first height, in operation S1720, the substrate may be loaded, and a substrate processing process may be performed on substrates of the next lot.

The relationship between the first height, the second height, and the third height according to an embodiment is as follows. First, the third height is the highest, and the third height may be greater than the second height of the substrate support portion to form a reaction space together with the gas supply part. In other words, the third height is a height for the temperature control portion to be lifted together as the substrate support portion is raised and lowered, and is the highest height. Referring to FIG. 15, the third height is indicated by h3.

The lowest is the first height, and the first height may be less than the second height (h2 in FIG. 14) of the substrate support portion for forming a reaction space together with the gas supply unit and for processing the substrate. In other words, the first height is a height for introducing/withdrawing a substrate to/from a lower space of a chamber located below the reaction space, and may be the lowest height. In some other embodiments, the first height and the second height may be the same.

Referring to FIG. 18, as in the embodiment of FIG. 17, in operation S1810, the substrate support portion is located at the first height, and in operation S1820, the substrate is loaded. Thereafter, in operation S1825, the substrate support portion is located at the third height to align the temperature control portion. In the embodiment of FIG. 17, the alignment operation of the temperature control portion is performed during an idle state after the processing of the substrate is completed, whereas in the embodiment of FIG. 18, the alignment operation of the temperature control portion is performed during the processing of the substrate.

After the alignment operation of the temperature control portion in operation S1825, in operation S1830, the substrate support portion is located at the second height to perform processing on the substrate. Thereafter, in operation S1840, the substrate support portion is located at the first height again to unload the substrate. The substrate loading, aligning the temperature control portion, performing the process, and unloading the substrate may be repeated until all substrates in a corresponding lot are processed.

Thereafter, in operation S1850, it is determined whether all the substrates of the corresponding lot have been processed, and when all are processed, substrates of the next lot are processed. To this end, in operation S1860, it is determined whether substrates of all lots have been processed, and when the substrates of all lots are not processed, operation S1870 of transferring substrates of the next lot to a reaction chamber may be performed.

When the substrates of the next lot are transferred to the reaction chamber, in operation S1820, the substrate is loaded as a subsequent operation. Because the substrate support portion is currently located at the first height for unloading in the previous operation, a substrate processing process for the substrates of the next lot may be performed without adjusting the height of a separate substrate support portion.

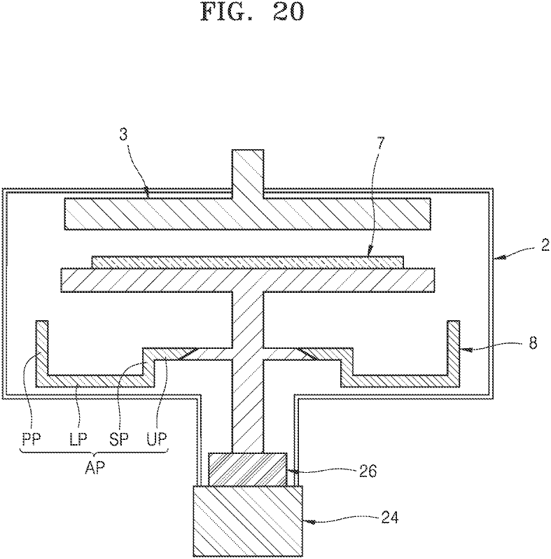

FIGS. 19 to 21 are views schematically illustrating a substrate processing apparatus and a substrate processing method using the same, according to embodiments. The substrate processing apparatus according to the embodiments may be a variation of the substrate processing apparatus and the substrate processing method according to the above-described embodiments. Hereinafter, repeated descriptions of the embodiments will not be given herein.

First, in order to describe a substrate processing apparatus according to embodiments, reference is made to FIG. 21 showing a substrate processing apparatus in an aligned state. As shown in FIG. 21, an aluminum plate AP included in the temperature control portion 8 of the substrate processing apparatus may be formed in a cylindrical shape with a convex central portion. In more detail, the aluminum plate AP may include an upper plate UP, a lower plate LP, an extension portion SP connecting the upper plate UP and the lower plate LP, and a peripheral plate PP protruding around the lower plate LP. The cylindrical aluminum plate AP may be implemented by the peripheral plate PP.

The upper plate UP may extend in a first direction (e.g., a horizontal direction), and may provide a convex central portion and the through hole TH. The lower plate LP may extend in the first direction and may provide a surface in contact with the chamber. As described above, a contact surface of the lower plate LP with the reactor wall 2 of the chamber (i.e., a lower surface of the lower plate LP in contact with the chamber) may be ground, and as a result, the contact surface of the lower plate LP with the reactor wall 2 may have a lower roughness than those of the other surfaces of the aluminum plate AP.

The extension portion SP may extend to connect the upper plate UP and the lower plate LP. The extension direction of the extension portion SP may be a second direction different from the first direction. Although the drawing shows that both the upper plate UP and the lower plate LP extend in the same first direction, the disclosure is not limited thereto, and the upper plate UP may extend in a direction other than the first direction. For example, the upper plate UP and the extension portion SP may extend from the lower plate LP to have a continuous inclination. In this case, the upper plate UP and the extension portion SP may extend from the lower plate LP to have a round profile together.

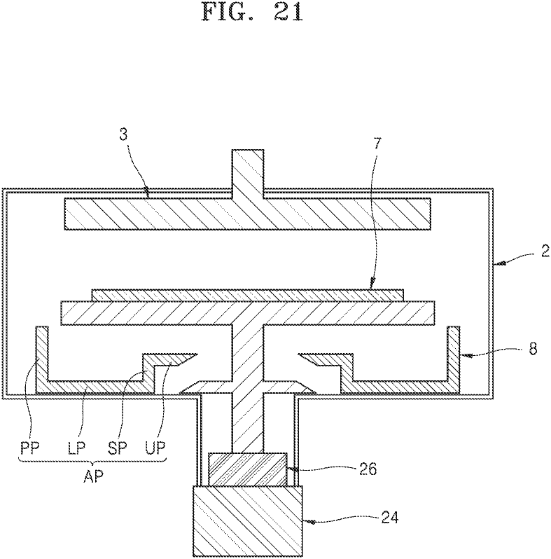

FIGS. 19 to 21 show an alignment operation of the temperature control portion 8 using the substrate processing apparatus described above. FIG. 19 shows a state in which the position of the aluminum plate AP is not symmetrical with respect to the center of the substrate support portion 4, and FIG. 20 illustrates raising a support rod to separate a lower surface of the aluminum plate AP from an upper surface of a chamber (i.e., self-aligning of the aluminum plate AP). FIG. 21 shows lowering a support rod to bring the lower surface of the aluminum plate AP into contact with the upper surface of the chamber.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

What is claimed is:

1. A method of manufacturing a substrate processing apparatus, the method comprising:
providing an aluminum plate having a through hole;
forming a temperature control portion by anodizing the aluminum plate; and
arranging the temperature control portion below a substrate support portion, wherein the temperature control portion is arranged so that a support rod of the substrate support portion passes through the through hole.

2. The method of claim 1, wherein the aluminum plate is black anodized during the forming of the temperature control portion.

3. The method of claim 1, wherein the aluminum plate is fixed by at least one component of the substrate processing apparatus during the arranging of the temperature control portion.

4. The method of claim 3, wherein the aluminum plate is fixed to the support rod.

5. The method of claim 3, wherein the substrate processing apparatus further comprises:
a connecting member provided on a lower surface of the substrate support portion, wherein
the aluminum plate is fixed to the substrate support portion through the connecting member.

6. The method of claim 3, wherein the substrate support portion is configured to move up and down at least by a moving unit, and
the aluminum plate is fixed to the moving unit.

7. The method of claim 1, wherein the aluminum plate is detachably seated on a chamber during the arranging of the temperature control portion.

8. The method of claim 7, wherein a lower surface of the aluminum plate is in contact with an upper surface of the chamber, and
radiant heat of a reaction space absorbed by the aluminum plate is radiated to the outside through the chamber.

9. The method of claim 8, wherein post-treatment of the aluminum plate is performed during the forming of the temperature control portion,
wherein a roughness of the lower surface of the aluminum plate is reduced during the post-treatment.

10. The method of claim 9, wherein the post-treatment includes grinding the lower surface of the aluminum plate.

11. The method of claim 7, wherein the substrate processing apparatus further comprises:
a heat transfer member arranged between a lower surface of the aluminum plate and an upper surface of the chamber,
wherein radiant heat of a reaction space absorbed by the aluminum plate is radiated to the outside through the heat transfer member and the chamber.

12. The method of claim 7, wherein an inner peripheral surface of the aluminum plate in which the through hole of the aluminum plate is formed includes a first slope.

13. The method of claim 12, wherein at least a portion of the support rod of the substrate support portion includes a second slope corresponding to the first slope.

14. The method of claim 13, further comprising:
performing an alignment operation of the temperature control portion while the support rod is raised so that the second slope of the support rod meets the first slope of the through hole of the aluminum plate.

15. The method of claim 14, further comprising:
aligning the temperature control portion to be coaxial with the support rod during the alignment operation.

16. The method of claim 14, wherein the alignment operation comprises:
raising the support rod to separate a lower surface of the aluminum plate from an upper surface of the chamber; and
lowering the support rod to bring the lower surface of the aluminum plate into contact with the upper surface of the chamber.

17. The method of claim 1, wherein the aluminum plate comprises:
an upper plate extending in a first direction to provide the through hole;
a lower plate extending in the first direction below the upper plate; and
an extension portion extending in a second direction different from the first direction to connect the upper plate to the lower plate.

18. A substrate processing apparatus for performing a plasma process, the substrate processing apparatus comprising:
a substrate support portion configured to support a substrate;
a chamber configured to house the substrate support portion; and
a temperature control portion arranged below the substrate support portion and configured to absorb radiant heat of a reaction space in the chamber generated during the plasma process.

19. The substrate processing apparatus of claim 18, wherein the temperature control portion includes a black anodized aluminum plate.

20. A substrate processing method comprising:
loading a substrate onto a substrate support portion by locating a support rod at a first height;
performing a process on the substrate by locating the support rod at a second height; and
aligning the support rod with a temperature control portion arranged below the substrate support portion by locating the support rod at a third height.
